(19) United States
(12) Patent Application Publication
(10) Pub. No.: US 2025/0107190 A1
(43) Pub. Date: Mar. 27, 2025

(54) SEMICONDUCTOR DEVICES INCLUDING SUBSTRATE STRUCTURE

(71) Applicant: Samsung Electronics Co., Ltd., Suwon-si (KR)

(72) Inventors: Jonggu LEE, Suwon-si (KR); Hyeonjin KIM, Suwon-si (KR); Kyungwon KANG, Suwon-si (KR); Hyunjae KANG, Suwon-si (KR); Youngha KIM, Suwon-si (KR); Jeonggil KIM, Suwon-si (KR); Jinman KIM, Suwon-si (KR); Sunghyup KIM, Suwon-si (KR); Sanghoon LEE, Suwon-si (KR)

(73) Assignee: Samsung Electronics Co., Ltd., Suwon-si (KR)

(21) Appl. No.: 18/652,010

(22) Filed: May 1, 2024

(30) Foreign Application Priority Data
Sep. 21, 2023 (KR) 10-2023-0126183

(51) Int. Cl. H01L 29/04; H01L 23/00; H01L 23/498

(52) U.S. Cl. CPC H10D 62/405; H01L 23/49844; H01L 24/08; H01L 24/94; H01L 2224/08146; H01L 2224/94; H01L 2924/3511

(57) ABSTRACT

A semiconductor device may include a first semiconductor structure including a first device layer on an upper surface of a first substrate structure, the first device layer including a first region of the semiconductor device; and a second semiconductor structure including a second device layer on a lower surface of a second substrate structure, the second device layer connected to the first device layer and including a second region of the semiconductor device. The first substrate structure may include a first wafer and a second wafer on the first wafer. The second wafer may be in contact with the first device layer. The second substrate structure may include a third wafer and a fourth wafer on a lower surface of the third wafer. The fourth wafer may be in contact with the second device layer. An upper surface of the second wafer may be a (100) crystal plane.

### CROSS-REFERENCE TO RELATED APPLICATION(S)

This application claims benefit of priority to Korean Patent Application No. 10-2023-0126183, filed on Sep. 21, 2023 in the Korean Intellectual Property Office, the disclosure of which is incorporated herein by reference in its entirety.

### BACKGROUND

Example embodiments of the present disclosure relate to a semiconductor device including a substrate structure.

A wafer corresponding to a semiconductor substrate may be used in a semiconductor device. A wafer may have a disk shape by slicing an ingot, a single crystal pillar formed by growing silicon (Si), gallium arsenide (GaAs), or the like. A surface of a wafer may have a specific crystal plane depending on a growth direction of the ingot, a cutting direction of the ingot, or the like. Depending on the crystal plane, mechanical/chemical properties of the wafer may vary.

### SUMMARY

An example embodiment of the present disclosure provides a semiconductor device including a substrate structure having improved uniformity of mechanical stiffness and/or chemical properties.

According to an example embodiment of the present disclosure, a semiconductor device may include a first semiconductor structure including a first substrate structure and a first device layer on an upper surface of the first substrate structure, the first device layer including a first region of the semiconductor device; and a second semiconductor structure including a second substrate structure and a second device layer on a lower surface of the second substrate structure, the second device layer connected to the first device layer and including a second region of the semiconductor device. The first substrate structure may include a first wafer and a second wafer on the first wafer. The second wafer may be in contact with the first device layer. The second substrate structure may include a third wafer and a fourth wafer on a lower surface of the third wafer. The fourth wafer may be in contact with the second device layer. An upper surface of the second wafer may be a (100) crystal plane.

According to an example embodiment of the present disclosure, a semiconductor device may include a first semiconductor structure including a first substrate structure and a first device layer on an upper surface of the first substrate structure, the first device layer including a first region of the semiconductor device; and a second semiconductor structure including a second substrate structure and a second device layer on a lower surface of the second substrate structure, the second device layer connected to the first device layer and including a second region of the semiconductor device. The first substrate structure may include a plurality of wafers stacked vertically. In the first substrate structure, the plurality of wafers may be stacked such that upper surfaces thereof may have a same crystal plane and crystal directions may be tilted with respect to each other or a portion of upper surfaces of the plurality of wafers may have different crystal planes.

According to an example embodiment of the present disclosure, a semiconductor device may include a first semiconductor structure including a first substrate structure, a first region of the semiconductor device on an upper surface of the first substrate structure, and a first bonding metal layer on the first region; and a second semiconductor structure including a second substrate structure, a second region of the semiconductor device on a lower surface of the second substrate structure, and a second bonding metal layer below the second region and bonded to the first bonding metal layer. The first substrate structure and the second substrate structure each may include a plurality of wafers stacked vertically.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a cross-sectional view illustrating a semiconductor device according to example embodiments of the present disclosure;

FIG. 2 is a cross-sectional view illustrating a semiconductor device according to example embodiments of the present disclosure;

FIGS. 3A and 3B are a cross-sectional view and an exploded perspective view illustrating a substrate structure according to example embodiments of the present disclosure;

FIGS. 4A and 4B are a cross-sectional view and an exploded perspective view illustrating a substrate structure according to example embodiments of the present disclosure;

FIG. 5 is a cross-sectional view illustrating a substrate structure according to example embodiments of the present disclosure;

FIG. 6 is an exploded perspective view illustrating a substrate structure according to example embodiments of the present disclosure;

FIGS. 7A to 7C are a cross-sectional view, an exploded perspective view, and a plan view illustrating a substrate structure according to example embodiments of the present disclosure, respectively;

FIG. 8 is a cross-sectional view illustrating a substrate structure according to example embodiments of the present disclosure;

FIG. 9 is an exploded perspective view illustrating a substrate structure according to example embodiments of the present disclosure;

FIG. 10 is a cross-sectional view illustrating a substrate structure according to example embodiments of the present disclosure;

FIGS. 11 and 12 are exploded perspective views illustrating a substrate structure according to example embodiments of the present disclosure;

FIGS. 13A and 13B are flowcharts illustrating a method of manufacturing a semiconductor device including a substrate structure according to example embodiments of the present disclosure;

FIGS. 14 and 15 are views illustrating a method of manufacturing a semiconductor device including a substrate structure according to example embodiments of the present disclosure; and

FIGS. 16A and 16B are views illustrating characteristics of a semiconductor device including a substrate structure according to example embodiments of the present disclosure.

### DETAILED DESCRIPTION

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, embodiments of the present disclosure will be described as follows with reference to the accompanying drawings.

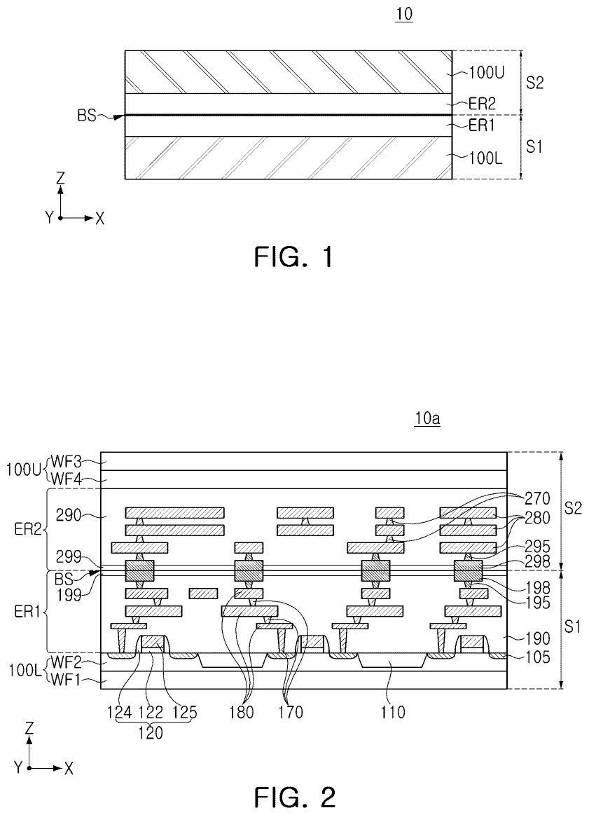

FIG. 1 is a cross-sectional view illustrating a semiconductor device according to example embodiments.

Referring to FIG. 1, a semiconductor device 10 may include a first semiconductor structure S1 and a second semiconductor structure S2 bonded to each other. The first semiconductor structure S1 may include a first substrate structure 100L and a first device layer ER1 disposed on an upper surface of the first substrate structure 100L. The second semiconductor structure S2 may include a second substrate structure 100U and a second device layer ER2 disposed on a lower surface of the second substrate structure 100U.

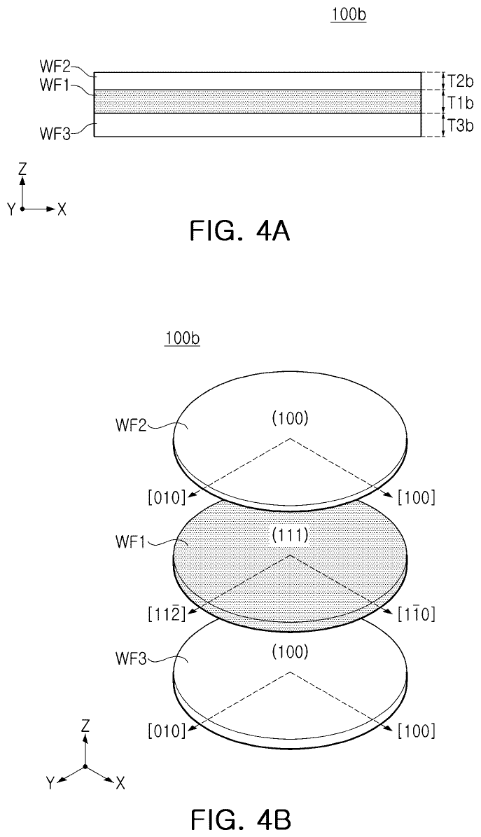

Each of the first substrate structure 100L and the second substrate structure 100U may include at least one wafer. In an example embodiment, at least one of the first substrate structure 100L and the second substrate structure 100U may include a plurality of wafers. Each of the plurality of wafers may include a group IV semiconductor or a group III-V compound semiconductor. For example, the group IV semiconductor may include silicon (Si), germanium (Ge), silicon carbide (SiC), or silicon-germanium (SiGe). A crystal structure of each of the plurality of wafers may be, for example, a diamond structure or a zinc blende structure. For example, the first substrate structure 100L and/or the second substrate structure 100U may include a plurality of wafers, which may be stacked such that upper surfaces may have the same crystal plane and crystal directions thereof may be tilted with respect to each other. For example, the first substrate structure 100L and/or the second substrate structure 100U may include a plurality of wafers, upper surfaces of at least a portion of which may have different crystal planes. The plurality of wafers may be directly bonded to each other through a surface treatment, such as a plasma treatment, or may be bonded to each other using an adhesive layer. In the case in which the plurality of wafers are bonded to each other using an adhesive layer, each of the first substrate structure 100L and the second substrate structure 100U may further include an adhesive layer disposed between the wafers. The specific structures of the first substrate structure 100L and the second substrate structure 100U will be described in greater detail below with reference to FIGS. 3A to 12.

The first device layer ER1 may include a first region of the semiconductor device, and the second device layer ER2 may include a second region of the semiconductor device. The semiconductor device may include, for example, a logic semiconductor device, a power semiconductor device, or a memory semiconductor device. The logic semiconductor device may include a micro-processor, for example, a central processing unit (CPU), a graphics processing unit (GPU), a field programmable gate array (FPGA), an application processor (AP), a digital signal processor, a cryptographic processor, a controller, or an application specific integrated circuit (ASIC). The power semiconductor device may include an ultra-small-sized power device such as a diode, a thyristor, or a transistor based on a compound material such as SiC or GaN. The memory semiconductor device may include a volatile memory device such as dynamic random access memory (DRAM), a static random access memory (SRAM), or the like, or a non-volatile memory device such as a flash memory.

In some example embodiments, the first region may include logic transistor devices, and the second region may include an interconnection structure electrically connected to the logic transistor devices, for example, a power line. In some example embodiments, the first region may include memory cells, and the second region may include circuit devices driving the memory cells.

The first semiconductor structure S1 and the second semiconductor structure S2 may be bonded to each other by, for example, hybrid bonding including copper (Cu)-to-copper (Cu) bonding and dielectric-to-dielectric bonding. A bonding surface BS may be formed between the first semiconductor structure S1 and the second semiconductor structure S2. In the bonding surface BS, the first device layer ER1 may oppose the second device layer ER2 and may be bonded to each other such that one surfaces thereof may be in contact with each other.

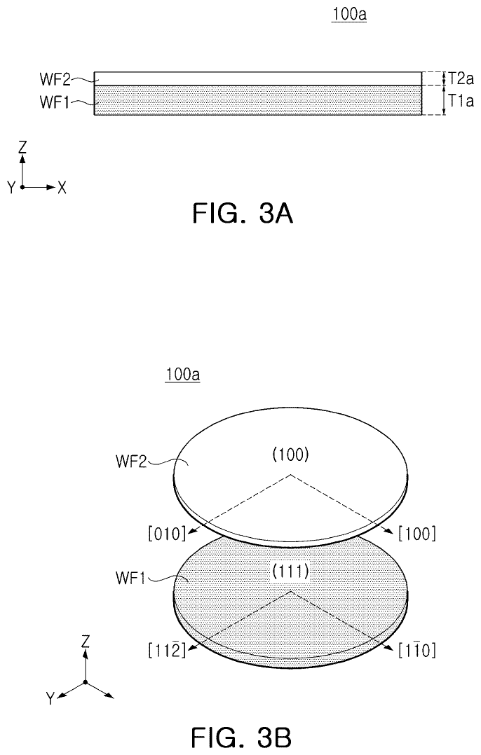

FIG. 2 is a cross-sectional view illustrating a semiconductor device according to example embodiments.

Referring to FIG. 2, a semiconductor device 10a illustrates an example embodiment of semiconductor device 10 in FIG. 1. In the semiconductor device 10a, a first substrate structure 100L may include first and second wafers WF1 and WF2 stacked in the Z-direction, and a second substrate structure 100U may include third and fourth wafers WF3 and WF4 stacked in the Z-direction.

In an example embodiment, an upper surface of the first wafer WF1 may be a (111) crystal plane, and an upper surface of the second wafer WF2 may be a (100) crystal plane. In this case, the first and second wafers WF1 and WF2 may be referred to as a (111) wafer and a (100) wafer, respectively. The first wafer WF1 and the second wafer WF2 may be stacked such that crystal directions thereof may be tilted with respect to each other or may not be tilted with respect to each other. The third and fourth wafers WF3 and WF4 may be (100) wafers, and may be stacked such that crystal directions thereof may be tilted with respect to each other. Also, the second wafer WF2 and the fourth wafer WF4, which may be bonded to each other, may be stacked such that crystal directions thereof may be tilted with respect to each other or may not be tilted with respect to each other. In some example embodiments, the first substrate structure 100L may have a structure of the second substrate structure 100U described above, and the second substrate structure 100U may have a structure of the first substrate structure 100L described above. In some example embodiments, each of the first substrate structure 100L and the second substrate structure 100U may include (100) wafers which may be stacked such that crystal directions thereof may be tilted with respect to each other. In this case, the tilted wafers may or may not form a bonding surface. In some example embodiments, each of the first substrate structure 100L and the second substrate structure 100U may have a structure in which a (111) wafer and a (100) wafer may be stacked and tilted, and the bonding surface may be defined by the (100) wafers.

However, in some example embodiments, the first substrate structure 100L and the second substrate structure 100U may be selected from various combinations of the substrate structures illustrated in FIGS. 3A to 12 below. Also, in some example embodiments, at least one of the first substrate structure 100L and the second substrate structure 100U may include a single wafer.

Device isolation layers 110 may be formed in the first substrate structure 100L, such that the active region may be defined. The device isolation layers 110 and the active region may be formed in the second wafer WF2 of the uppermost portion, but an example embodiment thereof is not limited thereto. Source/drain regions 105 including impurities may be disposed in a portion of the active region.

The first device layer ER1 may be disposed on an upper surface of the second wafer WF2. The first device layer ER1 may include circuit devices 120, first contact plugs 170, first interconnection lines 180, and first interlayer insulating layer 190 disposed on the first substrate structure 100L. The first device layer ER1 may further include first bonding vias 195, first bonding metal layers 198, and first bonding insulating layer 199, which are a bonding structure.

The circuit devices 120 may include a planar transistor. Each of the circuit devices 120 may include a gate dielectric layer 122, a spacer layer 124, and a gate electrode 125. The source/drain regions 105 may be disposed in the substrate structure 100 on both sides of the gate electrode 125. The interlayer insulating layer 190 may be disposed on the circuit device 120 on the substrate structure 100. The first contact plugs 170 may penetrate through the interlayer insulating layer 190 and may be connected to source/drain regions 105, and may connect first interconnection lines 180 on different levels to each other. An electrical signal may be applied to the circuit device 120 through the first contact plugs 170. In a region not illustrated, other contact plugs may also be connected to the gate electrode 125. The first interconnection lines 180 may be connected to the first contact plugs 170 and may be disposed in a plurality of layers.

The first bonding vias 195 may be disposed on an upper portion of the first interconnection lines 180 of an uppermost portion and may be connected to the first interconnection lines 180. At least a portion of the first bonding metal layers 198 may be connected to the first bonding vias 195 on the first bonding vias 195. The first bonding metal layers 198 may be connected to the second bonding metal layers 298 of the second semiconductor structure S2. The first bonding metal layers 198, together with the second bonding metal layers 298, may provide an electrical connection path according to bonding between the first semiconductor structure S1 and the second semiconductor structure S2. The first bonding vias 195 and the first bonding metal layers 198 may include a conductive material, for example, copper (Cu). The first bonding insulating layer 199 may be disposed around the first bonding metal layers 198. The first bonding insulating layer 199 may include a dielectric layer and, for example, may include at least one of SiN, SiON, SiCN, SiOC, SiOCN, and SiO.

The second device layer ER2 may be disposed on a lower surface of the fourth wafer WF4. The second device layer ER2 may include second contact plugs 270, second interconnection lines 280, and a second interlayer insulating layer 290 disposed on a lower surface of the second substrate structure 100U. The second device layer ER2 may further include second bonding vias 295, second bonding metal layers 298, and a second bonding insulating layer 299, which are a bonding structure.

The second contact plugs 270 and the second interconnection lines 280 may be disposed in a plurality of layers in the second interlayer insulating layer 290. In some example embodiments, the second interconnection lines 280 may be configured as power lines supplying power to the circuit devices 120.

The second bonding vias 295 and the second bonding metal layers 298 may be disposed below the second interconnection lines 280 of a lowermost portion. The second bonding vias 295 may connect the second interconnection lines 280 to the second bonding metal layers 298, and the second bonding metal layers 298 may be bonded to the first bonding metal layers 198 of the first semiconductor structure S1. The second bonding insulating layer 299 may be bonded and connected to the first bonding insulating layer 199 of the first semiconductor structure S1. The second bonding vias 295 and the second bonding metal layers 298 may include a conductive material, for example, copper (Cu). The second bonding insulating layer 299 may include a dielectric layer and, for example, may include at least one of SiO, SiN, SiCN, SiOC, SiON, and SiOCN.

A bonding surface BS may be formed between the first semiconductor structure S1 and the second semiconductor structure S2. The first and second semiconductor structures S1 and S2 may be bonded by bonding between the first bonding metal layers 198 and the second bonding metal layers 298 and bonding between the first bonding insulating layer 199 and the second bonding insulating layer 299. The bonding between the first bonding metal layers 198 and the second bonding metal layers 298 may be, for example, copper (Cu)-to-copper (Cu) bonding, and the bonding between the first bonding insulating layer 199 and the second bonding insulating layer 299 may be, for example, dielectric-to-dielectric bonding such as SiCN-to-SiCN bonding. The first and second semiconductor structures S1 and S2 may be bonded by hybrid bonding including copper (Cu)-to-copper (Cu) bonding and dielectric-to-dielectric bonding.

In the example embodiment, the semiconductor device 10a is illustrated as including transistor-type circuit devices 120, but the type of semiconductor device included in the semiconductor device 10a is not limited thereto. In some example embodiments, the semiconductor device may further include memory cells. In some example embodiments, in the semiconductor device, a memory cell structure may be bonded to a peripheral circuit region.

Hereinafter, the specific structure of the substrate structure including the first substrate structure 100L and the second substrate structure 100U in FIGS. 1 and 2 will be described in greater detail with reference to FIGS. 3A to 12.

FIGS. 3A and 3B are a cross-sectional view and an exploded perspective view illustrating a substrate structure according to example embodiments.

Referring to FIGS. 3A and 3B, a substrate structure 100a may include two first and second wafers WF1 and WF2. The second wafer WF2 may be stacked on an upper surface of the first wafer WF1. The first and second wafers WF1 and WF2 may be formed of the same material, and upper surfaces thereof may have different crystal planes. For example, the second wafer WF2 may be a (100) wafer, and the first wafer WF1 may be a (111) wafer.

The first and second wafers WF1 and WF2 may be stacked such that a direction of the second wafers WF2 and a [1-10] direction of the first wafer WF1 may become the same direction, but an example embodiment thereof is not limited thereto. In some example embodiments, the first and second wafers WF1 and WF2 may be disposed to be tilted with respect to each other at a desired and/or alternatively predetermined angle (θ), different from the example illustrated in FIG. 3B. For example, the angle (θ) may be in the range of 0°≤θ≤90°.

A second thickness T2a of the second wafer WF2 may be smaller than a first thickness T1a of the first wafer WF1. For example, the first thickness T1a may range from about 400 μm to about 1000 μm, and the second thickness T2a may range from about 10 μm or less, for example, from about 1 μm to about 10 μm. However, a thickness of the substrate structure 100a may decrease during a process of manufacturing the semiconductor device, thereby reducing a thickness of the first wafer WF1. In this case, relative sizes of the second thickness T2a of the second wafer WF2 and the first thickness T1a of the first wafer WF1 may vary.

Each of the first and second wafers WF1 and WF2 may have intrinsic mechanical and chemical properties depending on a crystal plane of upper surfaces thereof. For example, in the case of a wafer of which an upper surface is a (100) plane, mechanical properties such as stiffness may vary depending on directions. Accordingly, when a semiconductor device as illustrated in FIGS. 1 and 2 is manufactured using a single wafer, deformation or warpage of the wafer may occur, and non-uniform distribution of internal residual stress and strain may be induced. In this case, during a photolithography process for manufacturing a semiconductor device, or before and after a wafer to wafer (W2W) bonding process, such as bonding with a sustain wafer for a process and bonding between semiconductor structures, misalignment of patterns for forming a semiconductor device may occur such that overlay management may be difficult. However, in the case of the substrate structure 100a in an example embodiment, the first and second wafers WF1 and WF2 having different crystal planes are bonded to each other, such that mechanical properties described above may become uniform throughout the substrate structure 100a, such that, when the semiconductor device is manufactured, process difficulty may be reduced and defects may be reduced.

Specifically, a (100) wafer may exhibit relatively great warpage properties due to anisotropy of mechanical properties, and a (111) wafer may exhibit less warpage properties than that of (100) wafer. The substrate structure 100a in which a (100) wafer and a (111) wafer are stacked may exhibit warpage properties greater than (e.g., improved over) that of (111) wafer and less than that of a (100) wafer. As a result of simulation, it was confirmed that warpage in the substrate structure 100a was reduced by about 40% as compared to that of (100) wafer.

For example, when the substrate structure 100a is used as the first substrate structure 100L of the semiconductor device 10 in FIG. 1, wafers having different crystal planes may be stacked such that uniformity of mechanical properties may improve, and since the second wafer WF2 disposed in an uppermost portion and including the circuit device 120 formed thereon has a (100) plane, an etching rate may be assured during a process of forming the circuit device 120.

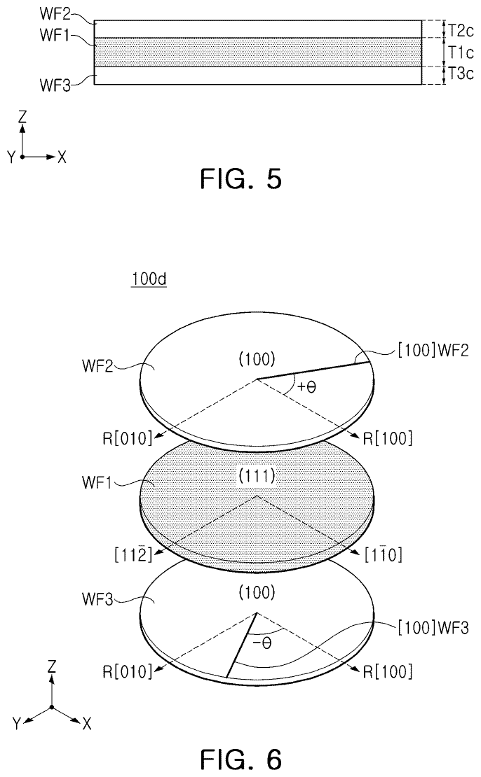

FIGS. 4A and 4B are a cross-sectional view and an exploded perspective view illustrating a substrate structure according to example embodiments.

Referring to FIGS. 4A and 4B, the substrate structure 100b may include first to third wafers WF1, WF2, and WF3 stacked in a vertical direction, for example, the Z-direction. The second wafer WF2 may be stacked on an upper surface of the first wafer WF1, and the third wafer WF3 may be stacked on a lower surface of the first wafer WF1. The first to third wafers WF1, WF2, and WF3 may be formed of materials having the same composition or different compositions. Upper surfaces of the second and third wafers WF2 and WF3 may have the same crystal plane, and an upper surface of the first wafer WF1 may have a crystal plane different from upper surfaces of the second and third wafers WF2 and WF3. For example, each of the upper surfaces of the second and third wafers WF2 and WF3 may be a (100) crystal plane, and the upper surface of the first wafer WF1 may be a (111) crystal plane.

The first to third wafers WF1, WF2, and WF3 may be stacked such that a direction of the second and third wafers WF2 and WF3 and a [1-10] direction of the first wafer WF1 may become the same direction. The second and third wafers WF2 and WF3 may be stacked without being tilted with respect to each other, but an example embodiment thereof is not limited thereto.

The first to third thicknesses T1b, T2b, and T3b of the first to third wafers WF1, WF2, and WF3 may be the same or different. For example, in some example embodiments, a second thickness T2b of the second wafer WF2 in an uppermost portion may be smaller than first and third thicknesses T1b and T3b, but an example embodiment thereof is not limited thereto.

The substrate structure 100b may have a structure including the second and third wafers WF2 and WF3, which has a relatively high chemical etching rate, and including the first wafer WF1, which has isotropic mechanical properties, interposed therebetween. Accordingly, mechanical properties of the entire substrate structure 100e may be improved, and an etching rate may be assured by the second wafer WF2 disposed in an uppermost portion and forming a semiconductor device.

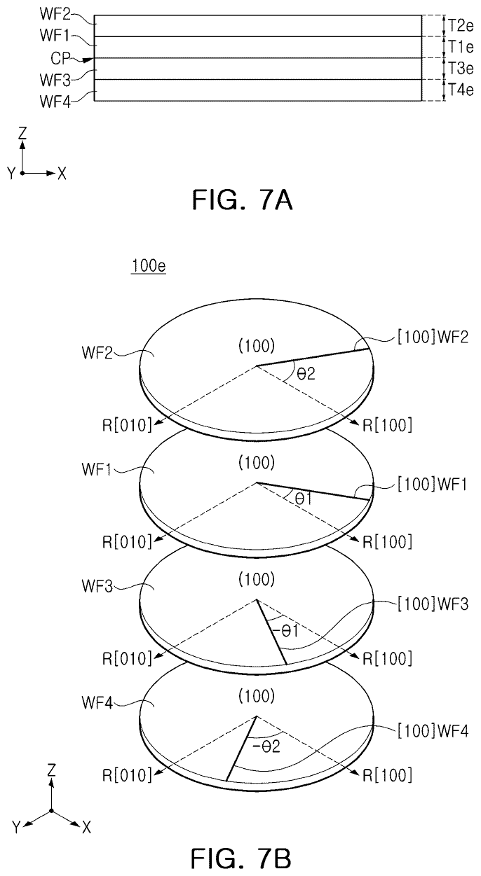

FIG. 5 is a cross-sectional view illustrating a substrate structure according to example embodiments.

Referring to FIG. 5, in a substrate structure 100c, the first to third thicknesses T1c, T2c, and T3c of the first to third wafers WF1, WF2, and WF3 may be different from the thicknesses in the example embodiment in FIGS. 4A and 4B. Specifically, the first thickness T1c of the first wafer WF1 may be greater than the second and third thicknesses T2c and T3c. However, in example embodiments, the relative sizes of the first to third thicknesses T1c, T2c, and T3c may vary.

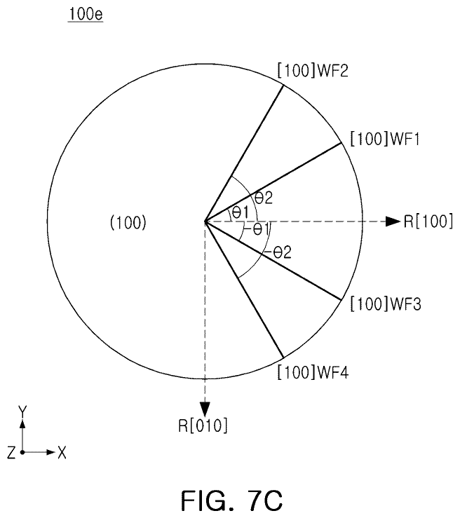

FIG. 6 is an exploded perspective view illustrating a substrate structure according to example embodiments.

Referring to FIG. 6, in a substrate structure 100d, different from the example embodiment in FIGS. 4A and 4B, the second and third wafers WF2 and WF3 may be stacked and tilted with respect to each other. Accordingly, crystal directions corresponding to one direction, for example, R[100] and R[1-10] directions, in the first to third wafers WF1, WF2, and WF3 may be different. The second wafer WF2 may be rotated in a counterclockwise direction by a first angle (θ) with respect to reference directions R[100] and R[010]. The reference directions may be understood as directions when the wafer is disposed without being tilted. The third wafer WF3 may be rotated in a counterclockwise direction by a second angle (−θ) with respect to the reference directions. The second angle (−θ) may be substantially the same as the first angle (θ).

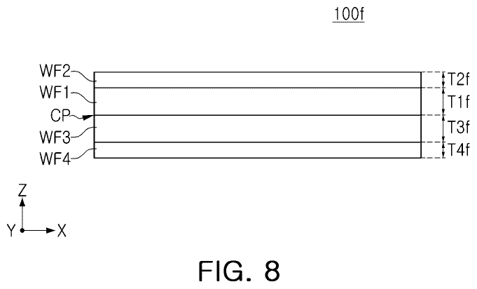

FIGS. 7A to 7C are a cross-sectional view, an exploded perspective view, and a plan view illustrating a substrate structure according to example embodiments, respectively.

Referring to FIGS. 7A to 7C, a substrate structure 100e may include first to fourth wafers WF1, WF2, WF3, and WF4 stacked in a vertical direction, for example, the Z-direction. The first to fourth wafers WF1, WF2, WF3, and WF4 may be stacked upwardly in an order of the wafer WF4, the third wafer WF3, the first wafer WF1, and the second wafer WF2. The second wafer WF2 may be stacked on an upper surface of the first wafer WF1, the third wafer WF3 may be stacked on a lower surface of the first wafer WF1, and the fourth wafer WF4 may be stacked on a lower surface of the third wafer WF3.

The first to fourth wafers WF1, WF2, WF3, and WF4 may be formed of the same material, and upper surfaces thereof may have the same crystal plane. For example, upper surfaces of the first to fourth wafers WF1, WF2, WF3, and WF4 may be (100) crystal planes. In some example embodiments, at least one of the first to fourth wafers WF1, WF2, WF3, and WF4 may be formed of a different material, and upper surfaces thereof may have the same crystal plane. The first to fourth thicknesses T1e, T2e, T3e, and T4e of the first to fourth wafers WF1, WF2, WF3, and WF4 may be substantially the same. The notion that elements are “substantially the same” may indicate that the element may be completely the same and may also indicate that the elements may be determined to be the same in consideration of errors or deviations occurring during a process. In example embodiments, the number of wafers forming the substrate structure 100e may vary.

The first to fourth wafers WF1, WF2, WF3, and WF4 may be stacked such that crystal directions thereof may be tilted with respect to each other. A substrate structure 100e may have a structure in which the first to fourth wafers WF1, WF2, WF3, and WF4 are angle-ply stacked. In FIGS. 7B and 7C, reference directions, a [100] direction (R[100]) and a [010] direction (R[010]) may be indicated in the example in which upper surfaces of the first to fourth wafers WF1, WF2, WF3, and WF4 are (100) crystal planes. The reference directions may be understood as directions when the wafer is disposed without being tilted.

In the substrate structure 100e, the tilting angles of the wafers in an upper portion and a lower portion may be symmetrical to each other with respect to a central surface CP corresponding to a center in the Z-direction, and the tilting directions may be opposite to each other. The first wafer WF1 may be rotated in a counterclockwise direction by a first angle (θ1) with respect to the reference directions. The second wafer WF2 may be rotated in a counterclockwise direction by a second angle (θ2) greater than the first angle (θ1) with respect to the reference directions. The third wafer WF3 may be rotated in a counterclockwise direction by the third angle (−θ1) with respect to the reference directions. The third angle (−θ1) may be substantially the same as the first angle (θ1). That is, the third wafer WF3 may be rotated in a clockwise direction by an angle substantially the same as the first angle (θ1) with respect to the reference directions. For example, the third wafer WF3 may be described as being rotated by the 360°-first angle (θ1) in a counterclockwise direction with respect to the reference directions. The fourth wafer WF4 may be rotated in a counterclockwise direction by the fourth angle (−θ2) with respect to the reference directions. The fourth angle (−θ2) may be substantially the same as the second angle (θ2). That is, the fourth wafer WF4 may be rotated in a clockwise direction by an angle substantially the same as the second angle (θ2) with respect to the reference directions. For example, the fourth wafer WF4 may be described as being rotated in a counterclockwise direction by the 360°-second angle (θ2) with respect to the reference directions.

The first angle (θ1) and the large second angle (θ2) may be different from each other and may be in the range of 0°≤θ1 and θ2≤360°. When the first to fourth wafers WF1, WF2, WF3, and WF4 have a diamond crystal structure and a zinc blende structure crystal structure, the first angle (θ1) and the large second angle (θ2) may be in the range of 0°≤θ1, θ2≤90°, which may be configured as above considering that, when the diamond crystal structure and the zinc blende structure crystal structure are rotated by 180°, the diamond crystal structure and the zinc blende structure crystal structure may become the same structure, such that the results when rotated 120° and −60° may be the same, and the results when rotated 240° and 60° may be the same. A difference between the first angle (θ1) and the third angle ( −θ1) and the difference between the second angle (θ2) and the fourth angle (−θ2) may be, for example, in the range of ±5°, considering errors in a process.

Accordingly, in the substrate structure 100e, the specific crystal directions of the first to fourth wafers WF1, WF2, WF3, and WF4 may be different. For example, as illustrated in FIGS. 7B and 7C, directions may be different. The first to fourth wafers WF1, WF2, WF3, and WF4 may have different crystal directions, for example, in the R[100] direction, which is a reference direction.

In the substrate structure 100e in an example embodiment, a plurality of wafers may be bonded by being tilted at different angles, and accordingly, mechanical properties may be uniform throughout the substrate structure 100e as compared to the case of using a single wafer, such that, when a semiconductor device is manufactured, process difficulty may be reduced and defects may be reduced.

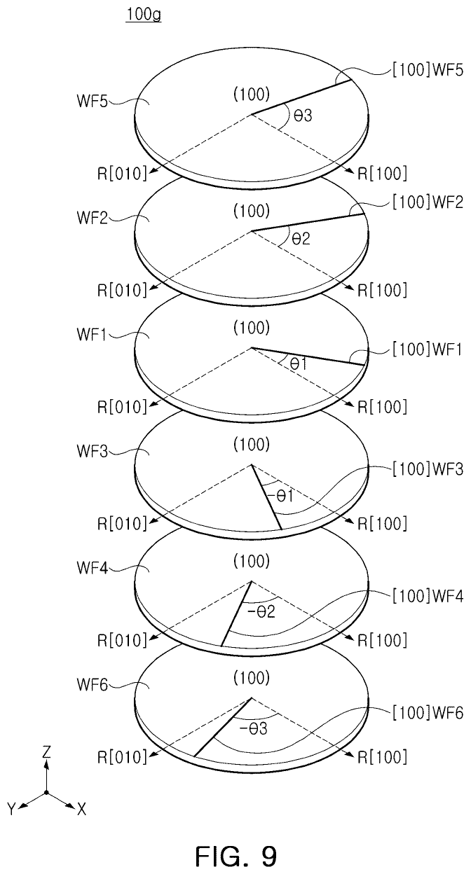

FIG. 8 is a cross-sectional view illustrating a substrate structure according to example embodiments.

Referring to FIG. 8, in a substrate structure 100f, thicknesses of the first to fourth wafers WF1, WF2, WF3, and WF4 may be different from the thicknesses in the example embodiment in FIGS. 7A to 7C. In the first to fourth wafers WF1, WF2, WF3, and WF4, wafers tilted at substantially the same angle may have substantially the same thickness. Wafers disposed symmetrically with respect to a central surface CP may have substantially the same thickness.

The first and third thicknesses T1f and T3f of the first wafer WF1 and the third wafer WF3 may be substantially the same, and the second and fourth thicknesses T2f and T4f of the second wafer WF2 and the fourth wafer WF4 may be substantially the same. For example, the first and third thicknesses T1f and T3f may be greater than second and fourth thicknesses T2f and T4f, but the relative sizes of first and third thicknesses T1f and T3f and second and fourth thicknesses T2f and T4f are not limited thereto.

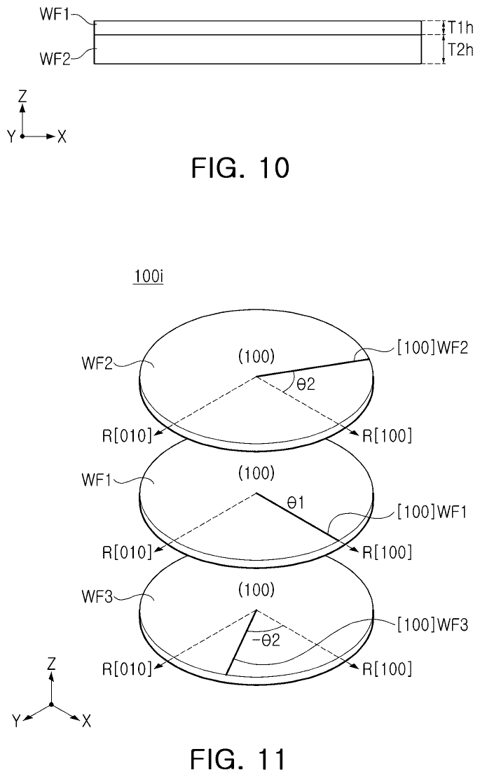

FIG. 9 is an exploded perspective view illustrating a substrate structure according to example embodiments.

Referring to FIG. 9, a substrate structure 100g may include the first to sixth wafers WF1, WF2, WF3, WF4, WF5, and WF6. The substrate structure 100g may further include fifth and sixth wafers WF5 and WF6, different from the example embodiment in FIGS. 7A to 7C. The fifth wafer WF5 may be stacked on an upper surface of the second wafer WF2, and the sixth wafer WF6 may be stacked on a lower surface of the fourth wafer WF4. The descriptions described above with reference to FIGS. 7A to 7C may be applied to the first to fourth wafers WF1, WF2, WF3, and WF4.

Upper surfaces of the first to sixth wafers WF1, WF2, WF3, WF4, WF5, and WF6 may be the same crystal plane, for example, a (100) plane. The fifth and sixth wafers WF5 and WF6 may be disposed such that the tilting angles may be symmetrical and the tilting directions thereof may be opposite to each other with respect to a central surface CP.

The fifth wafer WF5 may be rotated by a fifth angle (θ3), different from a first angle (θ1) and a second angle (θ2), in a counterclockwise direction with respect to reference directions. The sixth wafer WF6 may be rotated in a counterclockwise direction by a sixth angle (−θ3) with respect to the reference directions. The sixth angle (−θ3) may be substantially the same as the fifth angle (θ3). That is, the sixth wafer WF6 may be rotated in a clockwise direction by an angle substantially the same as the fifth angle (θ3) with respect to the reference directions. For example, the sixth wafer WF6 may be described as being rotated in a counterclockwise direction by a 360°-fifth angle (θ3) with respect to the reference directions. A thickness of the fifth wafer WF5 may be substantially the same as a thickness of the sixth wafer WF6.

In example embodiments, the number of wafers included in the substrate structure 100g may vary in a range in which the tilting angles are symmetrical and the tilting directions are opposite to each other with respect to the central surface CP.

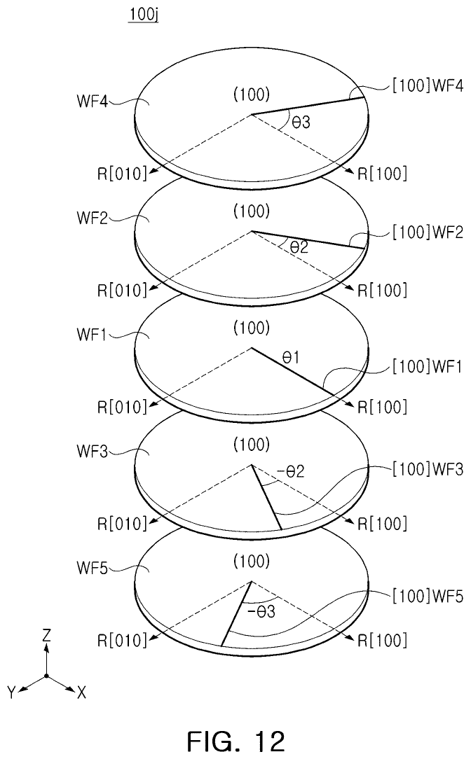

FIG. 10 is a cross-sectional view illustrating a substrate structure according to example embodiments.

Referring to FIG. 10, a substrate structure 100h may include first and second wafers WF1 and WF2. The substrate structure 100h may include only two wafers. The first wafer WF1 and the second wafer WF2 may or may not be tilted with respect to each other. For example, the first wafer WF1 and the second wafer WF2 may be stacked by selecting two arbitrary wafers in the example embodiment in FIG. 9. A thickness T2h of the second wafer WF2 may be greater than a thickness T1h of the first wafer WF1, but an example embodiment thereof is not limited thereto.

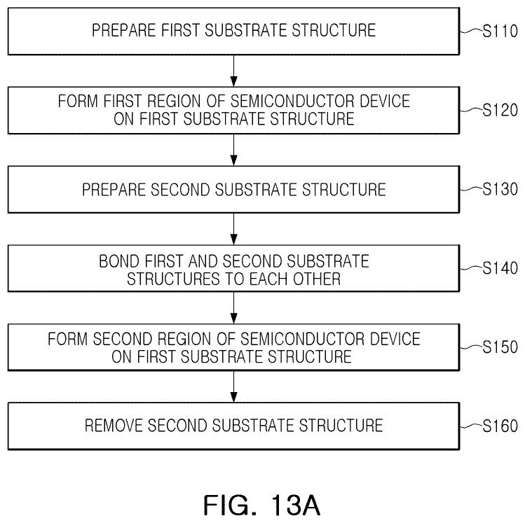

FIGS. 11 and 12 are exploded perspective views illustrating a substrate structure according to example embodiments.

Referring to FIG. 11, a substrate structure 100i may include first to third wafers WF1, WF2, and WF3. The second wafer WF2 may be stacked on an upper surface of the first wafer WF1, and the third wafer WF3 may be stacked on a lower surface of the first wafer WF1. Upper surfaces of the first to third wafers WF1, WF2, and WF3 may be the same crystal plane, for example, a (100) plane.

The first wafer WF1 may be stacked without being rotated or tilted. Accordingly, a first angle (θ1), which is a rotation angle of the first wafer WF1, may be 0°, and a [100] direction of the first wafer WF1 may match a reference direction R[100]. The second wafer WF2 may be rotated in a counterclockwise direction by a second angle (θ2) greater than the first angle (θ1) with respect to the reference directions. The third wafer WF3 may be rotated in a counterclockwise direction by a third angle (−θ2) with respect to the reference directions. The third angle (−θ2) may be substantially the same as the second angle (θ2). That is, the third wafer WF3 may be rotated in a clockwise direction by an angle substantially the same as the second angle (θ2) with respect to the reference directions. For example, the third wafer WF3 may be described as being rotated in a counterclockwise direction by a 360°-second angle (θ2) with respect to the reference directions.

A thickness of the second wafer WF2 may be substantially the same as a thickness of the third wafer WF3, and may be the same as or different from a thickness of the first wafer WF1.

Referring to FIG. 12, a substrate structure 100j may include first to fifth wafers WF1, WF2, WF3, WF4, and WF5. The second wafer WF2 may be stacked on an upper surface of the first wafer WF1, the third wafer WF3 may be stacked on a lower surface of the first wafer WF1, the fourth wafer WF4 may be stacked on an upper surface of the second wafer WF2, and the fifth wafer WF5 may be stacked on a lower surface of the third wafer WF3. The first to fifth wafers WF1, WF2, WF3, WF4, and WF5 may be formed of the same material, and upper surfaces thereof may be the same crystal plane, for example, a (100) plane.

The first wafer WF1 may be stacked without being rotated or tilted. Accordingly, a first angle (θ1), which is a rotation angle of the first wafer WF1, may be 0°, and a [100] direction of the first wafer WF1 may match a reference direction R[100]. The second wafer WF2 may be rotated in a counterclockwise direction by a second angle (θ2) greater than the first angle (θ1) with respect to the reference directions. The third wafer WF3 may be rotated in a counterclockwise direction by a third angle (−θ2) with respect to the reference directions. The third angle (−θ2) may be substantially the same as the second angle (θ2). The fourth wafer WF4 may be rotated in a counterclockwise direction by a fourth angle (θ3), different from the first angle (θ1) and the second angle (θ2), with respect to the reference directions. The fifth wafer WF5 may be rotated in a counterclockwise direction by a fifth angle (−θ3) with respect to the reference directions. The fifth angle (−θ3) may be substantially the same as the fourth angle (θ3).

A thickness of the second wafer WF2 may be substantially the same as a thickness of the third wafer WF3, and a thickness of the fourth wafer WF4 may be substantially the same as a thickness of the fifth wafer WF5.

As in the example embodiments in FIGS. 11 and 12, at least one of the wafers in the substrate structure may not be tilted with respect to the reference direction. However, even in this case, with respect to a central in a stacking direction, the wafers may be disposed such that the tilting angles may be symmetrical and the tilting directions are opposite to each other.

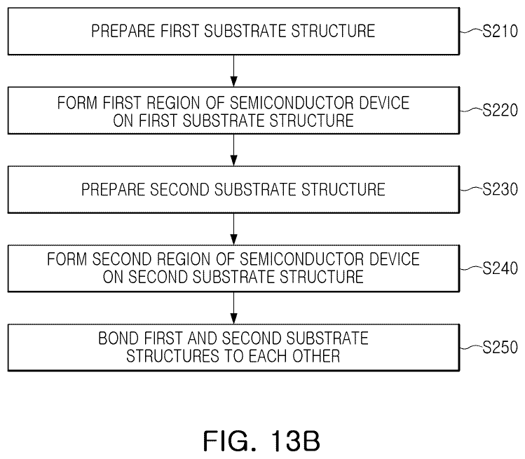

FIGS. 13A and 13B are flowcharts illustrating a method of manufacturing a semiconductor device including a substrate structure according to example embodiments.

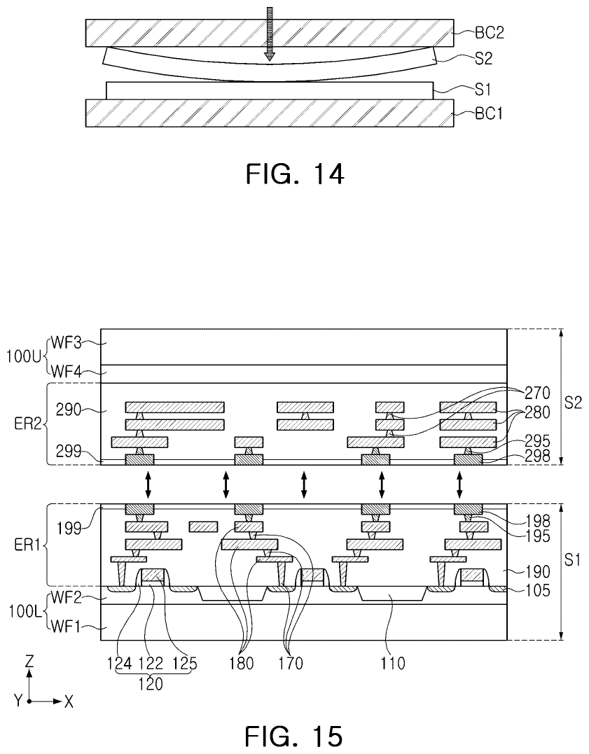

FIGS. 14 and 15 are views illustrating a method of manufacturing a semiconductor device including a substrate structure according to example embodiments.

First, referring to FIG. 13A, a method of manufacturing a semiconductor device may include preparing a first substrate structure (S110), forming a first region of the semiconductor device on the first substrate structure (S120), preparing a second substrate structure (S130), bonding the first and second substrate structures to each other (S140), forming a second region of the semiconductor device on the first substrate structure in the first and second substrate structures bonded to each other (S150), and removing the second substrate structure from the first and second substrate structures bonded to each other (S160).

In the preparing the first substrate structure (S110), the first substrate structure may be a structure in which the semiconductor device is formed. The first substrate structure may include a substrate structure according to one of the example embodiments described above with reference to FIGS. 3A to 12. Alternatively, in some example embodiments, the first substrate structure may be a single wafer.

In the forming the first region of the semiconductor device on the first substrate structure (S120), the semiconductor device formed on the first substrate structure may be, for example, a transistor, a memory cell, an interconnection structure, and in this process, at least a portion of the semiconductor device may be formed.

In the preparing the second substrate structure (S130), the second substrate structure may be a sustain substrate structure to support the first substrate structure during the process of forming the semiconductor device on the first substrate structure. The second substrate structure may include a substrate structure according to the example embodiments described above with reference to FIGS. 3A to 12. Alternatively, in some example embodiments, the second substrate structure may be a single wafer. At least one of the first and second substrate structures may include a substrate structure according to the example embodiments described above with reference to FIGS. 3A to 12.

The bonding the first and second substrate structures to each other (S140) may include attaching the first and second semiconductor structures S1 and S2, including the first and second substrate structures, to first and second bonding chucks BC1 and BC2, respectively, and bonding the first and second semiconductor structures S1 and S2 to each other, as illustrated in FIG. 14. The first semiconductor structure S1 may be attached to the first bonding chuck BC1 disposed below, and the second semiconductor structure S1 may be attached to the second bonding chuck BC2 disposed above. In some example embodiments, the first semiconductor structure S1 may be attached to the second bonding chuck BC2, and the second semiconductor structure S2 may be attached to the first bonding chuck BC1. In this process, the second substrate structure may be bonded to a back surface of the first substrate structure, that is, the surface on which the first region is not formed. The second substrate structure may be bonded to the first substrate structure using an adhesive layer, or may be bonded directly without an adhesive layer.

The forming the second region of the semiconductor device on the first substrate structure in the first and second semiconductor structures bonded to each other (S150) may include performing a semiconductor process on the first substrate structure while being supported by the second substrate structure, which is a sustain structure. For example, the semiconductor process may require supporting of the first substrate structure. The second region may be formed on the first region. In some example embodiments, when the semiconductor process is the first process for manufacturing the semiconductor device, process S120 may not be performed.

The removing the second substrate structure from the first and second substrate structures bonded to each other (S150) may include removing the second substrate structure after the semiconductor process is performed. Thereafter, a process of forming at least a portion of the semiconductor device on the first substrate structure may be further performed. If desired, during the process of manufacturing the semiconductor device, processes S130 to S160 may be further performed.

Referring to FIG. 13B, a method of manufacturing a semiconductor device may include preparing a first substrate structure (S210), forming a first region of the semiconductor device on the first substrate structure (S220), preparing a second substrate structure (S230), forming a second region of the semiconductor device on the second substrate structure (S240), and bonding the first and second substrate structures to each other (S250).

As for the preparing the first substrate structure (S210) and the forming the first region of the semiconductor device on the first substrate structure (S220), the descriptions of processes S110 and S120 described above with reference to FIG. 13A may be applied.

In the preparing the second substrate structure (S230), the second substrate structure may be a structure in which the semiconductor device is formed, similarly to the first substrate structure. The second substrate structure may include a substrate structure according to the example embodiments described above with reference to FIGS. 3A to 12. At least one of the first and second substrate structures may include a substrate structure according to the example embodiments described above with reference to FIGS. 3A to 12.

The forming the second region of the semiconductor device on the second substrate structure (S240) may include forming a portion of the semiconductor device on the second substrate structure separately from the first substrate structure. The second region of the semiconductor device may be electrically connected to the first region formed on the first substrate structure. As illustrated in FIG. 15, a first device layer ER1 corresponding to the first region of the semiconductor device may be formed on the first substrate structure 100L, and a second device layer ER2 corresponding to the second region of the semiconductor device may be formed on the second substrate structure 100U.

The bonding the first and second substrate structures (S250) may include bonding the first region and the second region to oppose each other. This process may include bonding the first and second semiconductor structures S1 and S2 to each other, which include the first and second substrate structures 100L and 100U, respectively, as illustrated in FIG. 15. The first device layer ER1 may include a first bonding structure including the first bonding metal layers 198, the second device layer ER2 may include a second bonding structure including the second bonding metal layers 298, and the first device layer ER1 and the second device layer ER2 may be bonded to each other by the first bonding structure and the second bonding structure. Thereafter, the first wafer WF1 of the first substrate structure of 100L and/or the third wafer WF3 of the second substrate structure of 100U may be thinned. However, the thinning process may not be performed. Accordingly, the semiconductor device 10a in FIG. 2 may be manufactured.

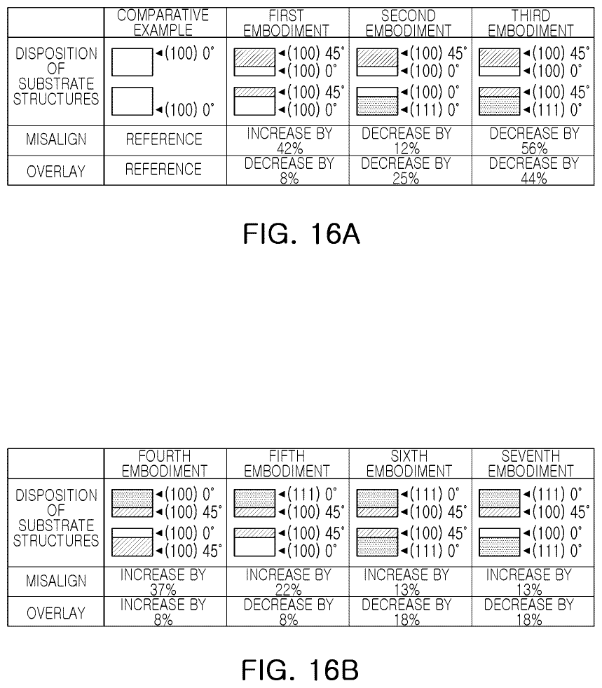

FIGS. 16A and 16B are views illustrating characteristics of a semiconductor device including a substrate structure according to example embodiments.

FIGS. 16A and 16B illustrate simulation results for misalign and overlay with respect to example embodiments in which first and second substrate structures are bonded to each other as illustrated in FIG. 14. Misalign may refer to distortion caused by bonding between the first and second substrate structures, and overlay may refer to alignment between patterns when a photolithography process is performed on the entire bonded structure.

The comparative example may correspond to a structure in which each of the first and second substrate structures may be a single wafer having a (100) plane. The first to seventh example embodiments may have a wafer stack structure of a first substrate structure in a lower portion and a second substrate structure in an upper portion as illustrated in FIGS. 16A and 16B.

Specifically, in the first example embodiment, each of the first and second substrate structures may have a structure in which two (100) wafers are stacked and tilted with respect to each other, a tilting angle may be 45°, and the (100) wafers bonded to each other may also be bonded in a tilted state. In the second example embodiment, the first substrate structure of a lower portion may have a structure in which a (111) wafer and a (100) wafer are stacked without being tilted as in the example embodiment in FIGS. 3A and 3B. In the third example embodiment, the first substrate structure of a lower portion may have a structure in which a (111) wafer and a (100) wafer are stacked and the (100) wafer is stacked by being tilted 45° with respect to the (111) wafer. Each of the first and second substrate structures in other example embodiments may also be understood as above from the illustrated example.

As a result of the simulation, as compared to the comparative example, misalign was reduced in the second and third example embodiments, and overlay was reduced in the entirety of the example embodiments other than the fourth example embodiment. For example, in the third example embodiment, overlay was reduced by about 44%, and misalignment due to bonding was also reduced by about 56%. Accordingly, it may be indicated that, when the semiconductor structures each including a substrate structure are bonded as illustrated in FIG. 15, overlay properties may be improved, and in some example embodiments, misalignment may also be improved.

According to the aforementioned example embodiments, by stacking the plurality of wafers by optimizing the composition or the tilting angle of crystal planes of thereof, a substrate structure having improved uniformity of mechanical stiffness and assured chemical properties may be provided. By bonding the semiconductor structures including the substrate structure, a semiconductor device having improved reliability and mass production may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure including a first substrate structure and a first device layer on an upper surface of the first substrate structure, the first device layer including a first region of the semiconductor device; and
a second semiconductor structure including a second substrate structure and a second device layer on a lower surface of the second substrate structure, the second device layer connected to the first device layer and including a second region of the semiconductor device, wherein
the first substrate structure includes a first wafer and a second wafer on the first wafer,
the second wafer is in contact with the first device layer,
the second substrate structure includes a third wafer and a fourth wafer on a lower surface of the third wafer,
the fourth wafer is in contact with the second device layer, and
an upper surface of the second wafer is a (100) crystal plane.

2. The semiconductor device of claim 1, wherein a lower surface of the fourth wafer is a (100) crystal plane.

3. The semiconductor device of claim 2, wherein a crystal direction of the second wafer and a crystal direction of the fourth wafer are tilted with respect to each other.

4. The semiconductor device of claim 1, wherein an upper surface of the first wafer is a (111) crystal plane.

5. The semiconductor device of claim 1, wherein
an upper surface of the first wafer is a (100) crystal plane, and
the first wafer and the second wafer are stacked such that a crystal direction of the first wafer and a crystal direction of the second wafer are tilted with respect to each other by a first angle.

6. The semiconductor device of claim 5, wherein the first angle (θ1) is in a range of 0°≤θ1≤90°.

7. The semiconductor device of claim 1, wherein a lower surface of the third wafer is a (111) crystal plane.

8. The semiconductor device of claim 1, wherein a lower surface of the third wafer is a (100) crystal plane.

9. The semiconductor device of claim 8, wherein
a lower surface of the fourth wafer is a (100) crystal plane, and
the third wafer and the fourth wafer are stacked such that a crystal direction of the third wafer and a crystal direction of the fourth wafer are tilted with respect to each other.

10. The semiconductor device of claim 1, wherein
the first region includes a transistor, and
the second region includes an interconnection structure electrically connected to the transistor.

11. The semiconductor device of claim 1, wherein
the first device layer further includes a first bonding metal layer on the first region, and
the second device layer further includes a second bonding metal layer below the second region, and
the second bonding metal layer is bonded to the first bonding metal layer.

12. The semiconductor device of claim 1, wherein the second wafer has a thickness in a range of 1 μm to 5 μm.

13. A semiconductor device, comprising:
a first semiconductor structure including a first substrate structure and a first device layer on an upper surface of the first substrate structure, the first device layer including a first region of the semiconductor device; and
a second semiconductor structure including a second substrate structure and a second device layer on a lower surface of the second substrate structure, the second device layer connected to the first device layer and including a second region of the semiconductor device, wherein
the first substrate structure includes a plurality of wafers stacked vertically, and
in the first substrate structure, the plurality of wafers are stacked such that upper surfaces thereof have a same crystal plane and crystal directions are tilted with respect to each other or a portion of upper surfaces of the plurality of wafers have different crystal planes.

14. The semiconductor device of claim 13, wherein
the first substrate structure includes a first wafer and a second wafer on the first wafer,
the second wafer is in contact with the first device layer, and
an upper surface of the second wafer is a (100) crystal plane.

15. The semiconductor device of claim 14, wherein an upper surface of the first wafer is a (111) crystal plane.

16. The semiconductor device of claim 13, wherein
the plurality of wafers include a first wafer tilted at a first angle in a counterclockwise direction from a reference direction horizontal and a second wafer tilted at the first angle in a clockwise direction from the reference direction, and
the reference direction is horizontal to an upper surface of the first substrate structure.

17. The semiconductor device of claim 13, wherein
the plurality of wafers include a first wafer, a second wafer, and a third wafer,
a reference direction is horizontal to an upper surface of the first substrate structure,
the first wafer has a first crystal direction in a direction rotated by a first angle in a counterclockwise direction from the reference direction,
the second wafer has the first crystal direction in a direction rotated by a second angle in the counterclockwise direction from the reference direction, and
the third wafer has the first crystal direction in a direction rotated by a third angle in the counterclockwise direction from the reference direction.

18. A semiconductor device, comprising:
a first semiconductor structure including a first substrate structure, a first region of the semiconductor device on an upper surface of the first substrate structure, and a first bonding metal layer on the first region; and
a second semiconductor structure including a second substrate structure, a second region of the semiconductor device on a lower surface of the second substrate structure, and a second bonding metal layer below the second region and bonded to the first bonding metal layer, wherein
the first substrate structure and the second substrate structure each include a plurality of wafers stacked vertically.

19. The semiconductor device of claim 18, wherein
the first substrate structure includes a first wafer and a second wafer, and
a crystal plane of an upper surface of the first wafer is different from a crystal plane of an upper surface of the second wafer.

20. The semiconductor device of claim 18, wherein
the first substrate structure includes a first wafer,
the upper surface of the first substrate structure is an upper surface of the first wafer,
the second substrate structure includes a second wafer,
the lower surface of the second substrate structure is a lower surface of the second wafer,
the upper surface of the first wafer and the upper surface of second wafer have a same crystal plane, and
a crystal direction of the first wafer and a crystal direction of the second wafer are tilted with respect to each other.
